(19) United States
(12) Patent Application Publication
(10) Pub. No.: US 2025/0076767 A1
(43) Pub. Date: Mar. 6, 2025

(54) SYSTEMS AND METHODS FOR DIGITAL LITHOGRAPHY SCAN SEQUENCING

(71) Applicant: Applied Materials, Inc., Santa Clara, CA (US)

(72) Inventors: Ulrich Mueller, Berkley, CA (US); Thomas L. Laidig, Richmond, CA (US); Rudolf C. Brunner, Menlo Park, CA (US)

(21) Appl. No.: 18/486,726

(22) Filed: Oct. 13, 2023

Related U.S. Application Data
(60) Provisional application No. 63/536,198, filed on Sep. 1, 2023.

(51) Int. Cl. G03F 7/20

(52) U.S. Cl. CPC G03F 7/2051

(57) ABSTRACT

A digital lithography system includes a stage configured to support a substrate, a bridge disposed above the stage, and a first lithographic processing unit coupled to the bridge. The first lithographic processing unit coupled to the bridge can include a scanning unit, a lithographic exposure unit, and an optical system shared by the scanning unit and the lithographic exposure unit. The scanning unit is to use the optical system to generate measurements of the substrate during a measurement operation, and the lithographic exposure unit is to use the optical system to perform digital lithographic exposure of the substrate using the optical system during an exposure operation.

### CROSS-REFERENCE AND RELATED APPLICATIONS

This application claims the benefit of U.S. Provisional Patent Application No. 63/536,198; filed on Sep. 1, 2023

### TECHNICAL FIELD

The instant specification generally relates to electronic device manufacturing. More specifically, the instant specification relates to a digital lithography system used in electronic device manufacturing.

### BACKGROUND

Digital lithography is a specialized form of photolithography used to digitally create a pattern onto a surface of a substrate without the use of a traditional, or physical, photomask. The absence of a traditional photomask, and the versatility enabled by such digital systems, enable both higher processing speed and higher resolutions for lithographic processing systems. Such digital systems have proven advantageous in various applications, including printed circuit board (PCB) patterning, solder masks, flat panel displays, laser marking, and other digital exposure processes that demand sophisticated levels of speed and precision. Further benefits derived from the introduction of such digital systems include reductions in material cost, enhanced production rates, and increased system adaptability, through the ability to effect rapid changes to a lithographic exposure pattern.

To effect lithography without a photomask, digital lithography systems employ digital exposure units, which can selectively expose a substrate surface to an actinic light source (e.g., often a UV light source). Such selective exposure can be precisely controlled to create patterns, or paths in the surface material of a substrate. Such patterns or paths can then be used as a format for the electrical connection paths between surface features (e.g. integrated electronics modules).

Often, the specific pattern for exposure can be from a predesigned template, or guide, for the exposure process. Such a template, or surface profile “map,” can be used by exposure units to create an intended surface profile. For example, in the application of display manufacturing, a glass substrate may undergo preprocessing that installs prefabricated electrical modules onto a surface (arranged in accordance with a surface profile template). Such modules can include computer memory, sensors, logic relays, antennas, etc., that can be placed on a substrate surface. After such processing, and placement of modules, digital lithography can then be used to form partial, or complete, patterns in the surface material. Such patterns can be further processed downstream, to create conductive connection paths that enable electrical communications, power transmissions, and other necessary transmissions between modules and surface features of a substrate.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one aspect of the present disclosure, a digital lithography system is provided. The system includes, a stage configured to support a substrate, a bridge disposed above the stage, and a first lithographic processing unit coupled to the bridge. In some aspects, the first lithographic processing unit coupled to the bridge includes an optical system configured to transmit optical signals both to and from the substrate and the first lithographic processing unit. In some aspects, the first lithographic processing unit includes a scanning unit configured to capture measurements associated with the substrate via the optical system. In some aspects, the lithographic exposure unit includes a lithographic exposure unit configured to perform digital lithographic exposure of the substrate via the optical system.

According to one aspect of the disclosure, a digital lithography system is provided. The system includes a stage configured to support a first substrate at a first region and a second substrate at a second region, a bridge disposed above the stage, a first scanning unit coupled to the stage and disposed above the stage at the first region, and a first lithographic exposure unit coupled to the stage and disposed above the stage at the second region. In some aspects, the first lithographic exposure unit is to perform digital lithographic exposure of a first substrate disposed at the second region at a same time that the first scanning unit is to generate measurements of a second substrate disposed at the first region.

According to one aspect of the disclosure, a digital lithography system is provided. The system includes a stage configured to support a substrate, a bridge disposed above the stage, a first scanning unit coupled to the bridge and disposed above the stage at a first region, and a first lithographic exposure unit coupled to the bridge and disposed above the stage at a second region. In some aspects, the first scanning unit is to perform scanning of a first portion of the substrate while the first portion of the substrate is positioned in the first region at a first time, and to perform scanning of a second portion of the substrate while the second portion of the substrate is positioned in the first region at a second time. In some aspects, the first lithographic exposure unit is to perform digital lithographic exposure of the first portion of the substrate while the first portion of the substrate is positioned in the second region at the second time based at least in part on the scanning performed of the first portion of the substrate at the first time.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1A illustrates a top-down view of a substrate and corresponding surface features, in accordance with some embodiments of the present disclosure.

FIG. 1B illustrates a top-down view of a package on a surface of a substrate, in accordance with some embodiments of the present disclosure.

FIG. 1C illustrates a top-down view of an integrated module of a package, in accordance with some embodiments of the present disclosure.

FIG. 2 illustrates a top-down view of a lithographic processing system suitable for performing a TTL method of metrological scanning and lithographic exposure, in accordance with some embodiments of the present disclosure.

FIG. 3A illustrates a combined lithographic unit, in accordance with some embodiments of the present disclosure.

FIG. 3B illustrates a combined lithographic unit, in accordance with some embodiments of the present disclosure.

FIG. 3C a combined lithographic unit, in accordance with some embodiments of the present disclosure.

FIG. 4 illustrates a top-down view of a lithographic processing system, in accordance with some embodiments of the present disclosure.

FIG. 5 illustrates an example process flow of a substrate through the system of FIG. 4, in accordance with some embodiments of the present disclosure.

FIG. 6 illustrates a top-down view of a lithographic processing system, in accordance with some embodiments of the present disclosure.

FIG. 7 illustrates an example process flow of a substrate through the system of FIG. 6, in accordance with some embodiments of the present disclosure.

FIG. 8 illustrates an embodiment of a diagrammatic representation of a computing device associated with a substrate manufacturing system.

### DETAILED DESCRIPTION

Digital lithography faces some challenges in modem-day applications. One such challenge is the effect of variations in manufacturing conditions on substrates and their surface profiles (e.g. surface features). For example, each substrate and their respective surface features can undergo unique manufacturing conditions that introduce unique errors into the substrate surface profile. These errors can uniquely alter the position and footprint of substrate surface features from their intended placement, and so introduce idiosyncratic errors into the surface profile.

If the lithographic processing system proceeds as originally planned, without accounting for such errors, then a created connection path may be misaligned and therefore not connect to an intended connection point. Thus, real surface profiles can stray from intended surface profiles, and create functional defects in the substrate surface profile features, components, and performance. If, for example, components do not correctly connect to other components due to misalignment, then operation of a device may be compromised.

A method for dealing with misalignment between components or substrate surface features is to (prior to exposure) scan the substrate for any positional errors via a metrological scanning unit, and capture real surface profile feature data. Using this captured data, and a target surface profile template, a computing subsystem can analyze the differences between an actual surface profile and the target surface profile and insert remediations into (i.e., update) the target surface profile exposure template. In such a way, the target surface profile exposure templates can be remediated and updated, based on captured data, to accurately create connections on an altered substrate surface profile.

Current implementations for generating remediations for substrate surface profiles face some challenges. For example, implementing remedial action can be slow and computationally expensive. A metrological unit and its placement should be calibrated, and a substrate should be thoroughly scanned by the metrological unit. Afterwards, computer processing to develop a remediated template can take valuable computational time. Such time is increased if a complex machine learning model or similar computer method is used.

Increased wait-time due to metrological scanning, data processing, development of the remediated template, and lithographic exposure serves to increase total processing time, decrease throughput, and occupy valuable computational resources.

Another obstacle is that a remediated template can sometimes perpetuate defects, through the effects of offsets introduced in between metrological scanning and lithographic exposure. For example, when a substrate is placed within a metrological scanning system and data is captured, any offset or miscalibration becomes “baked” or fixed into the captured data, and therefore, the remediated template. After the remediated template is developed, the substrate may be placed into a separate, lithographic exposure system to undergo exposure. However, the lithographic exposure system abnormalities, offsets, and calibrations may be different than those of the metrological system. Thus, the remediated template may already include offset errors even prior to delivery to exposure systems and exposure processing, in part due to such system variations. For example, a warped substrate may be clamped (e.g., electrostatically chucked) during metrological scanning, which may pull the substrate flat and modify a surface profile of the substrate. The warped substrate may then be moved to a new location and again be clamped at the new location for lithographic exposure. Clamping the substrate at the new location may cause the surface profile to be modified in a different manner than it was modified when clamped at a first location during metrological scanning. These differences can introduce errors.

Aspects and implementations of the present disclosure address these and other shortcomings of existing technologies by incorporating strategies that reduce delay between metrological scanning, surface profile processing, remediated template development, and exposure processing. The present disclosure further incorporates strategies to minimize substrate manipulation between scanning and lithographic exposure, and therefore introduction of system variational errors.

In the disclosed digital lithography system, metrological scanning and lithographic exposure processing can be done in parallel and/or in sequence via several methods, including a through the lens (TTL) method, a first in first out (FIFO) method, or a scan ahead (SA) method. As will be discussed below, by making use of these methods, multiple substrates can be metrologically scanned and lithographically exposed in parallel. Thus, process wait and idle times can be reduced, increasing throughput, maximizing efficiency, and capitalizing on available resources. Additionally, errors introduced by additional handling between scanning and lithographic exposure may also be reduced or eliminated in some embodiments.

In embodiments, the current system also works towards reducing offset error introduction from the metrological subsystem by combining a metrological unit and a lithographic exposure unit into a consolidated lithographic processing unit. Thus, in some embodiments, the substrate can be metrologically scanned and lithographically exposed while disposed within a single system. This reduces offset errors that can be introduced while moving the substrate, such as errors introduced from variations between (what would be) separate systems and components. Examples of errors that may be reduced or eliminated include errors introduced from variations in substrate supporting mechanisms, from transfer robot calibrations and/or from substrate placement, with respect to the two systems.

For remediation processing, or template updates, in some embodiments, the system may employ a computing subsystem to intake a target exposure template, together with metrological scanning data of a substrate surface profile, and produce an updated (i.e. remediated) exposure template. Such systems and methods will be described now, in detail.

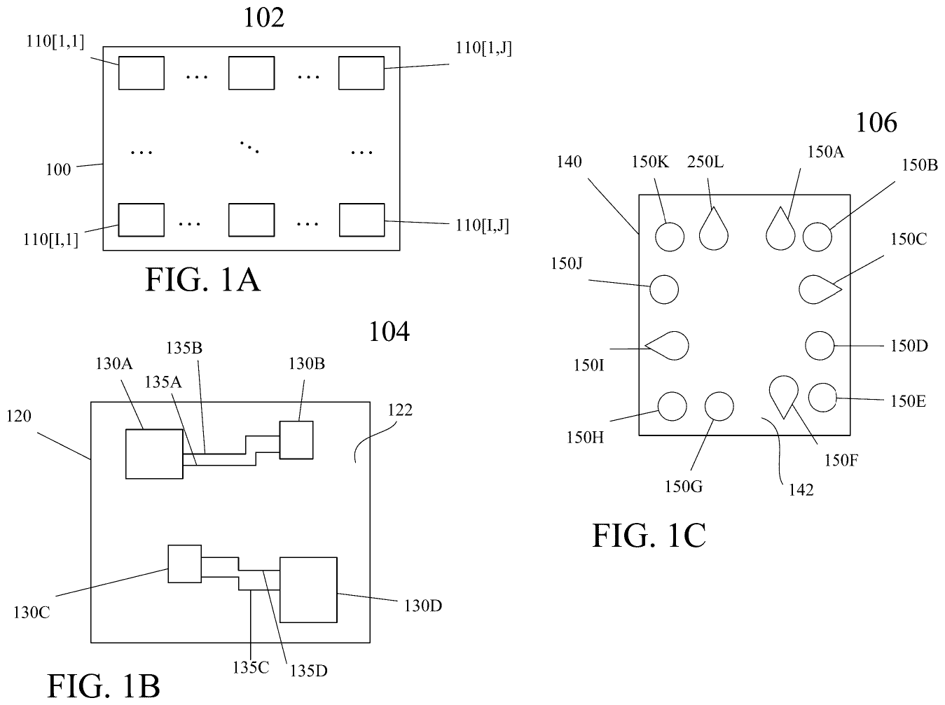

FIG. 1A illustrates a top-down view of a substrate and corresponding surface features, in accordance with some embodiments of the present disclosure.

In some embodiments, as seen in substrate surface profile view 102 of FIG. 1A, a substrate 100 can include individual packages 110, or groups of integrated modules, on the surface of the substrate 100. The packages 110 can be arranged, in some instances, in a grid formation as seen in FIG. 1A, such that a specific package on the substrate can be denoted by package 110[i,j], where i∈[1,I] and j∈[1,J].

In some embodiments, substrate 100 may be a rectangular substrate, with packages formed into the surface according to a grid formation. In other embodiments, a different arrangement for the packages 110 may be used, and/or a different substrate shape may be used, to facilitate scanning, exposure, and/or other processes. Such a substrate shape and/or contour may be circular, hexagonal, or amorphous, etc. One of ordinary skill in the art, having the benefit of this disclosure will be able to design multiple such shapes for a substrate, and multiple layout designs for the packages installed on the surface of a substrate.

In some embodiments, substrate 100 may be a glass substrate. In some embodiments, substrates 100 may be a wafer (e.g., such as a semiconductor wafer). In some embodiments, substrates 100 be circular, or square, or any other shape suitable for substrate manufacturing.

In some embodiments, substrate 100 may be of a thickness of a range of 0.7-0.5 millimeters, or of a range of 0.6-0.8 millimeters, or of a range of 0.4-1.0 millimeters. In some embodiments, the substrate 100 may be of a different thickness. In some embodiments, substrate 100 may be warped. In some embodiments, substrate 100 may be pulled flat by a chuck or other substrate support during scanning and/or during lithographic exposure. In some embodiments, on substrate 100 being pulled flat, an arrangement of packages 110 and/or sub-components of packages on substrate 100 may change (e.g., distances between packages 110 and/or sub-components of packages and/or relative positions of packages 110 and/or sub-components of packages may change while the substrate is chucked).

In some embodiments, substrate 100 may be of one or more materials including borosilicate glass, soda-lime glass, quartz glass, aluminosilicate glass, lead glass, laminated glass, tempered glass, or any one or more glass or other materials commonly used within electronic device manufacturing systems.

In some embodiments, substrate 100 may be of one or more materials including Silicon, Germanium, Gallium Arsenide (GaAs), silicon dioxide (SiO2 or silica), Indium Phosphide (InP), Silicon Germanium (SiGe), Silicon Carbide (SiC), Gallium Nitride (GaN), or any one or more materials commonly used within electronic device manufacturing systems.

In some embodiments, substrate 100 may be formed from one material. In other embodiments, substrate 100 may be formed from a mixture of materials, (e.g., a homogenous mixture of materials). In other embodiments, substrate 100 may be made of one or more stacked layers of one or more differing materials. By way of example, substrate 100 may be a silicon on insulator (SOI) wafer, where a layer of SiO₂ is disposed vertically between two insulative silicon layers.

FIG. 1B illustrates a top-down view 104 of a package 120 on a surface of a substrate, in accordance with some embodiments. In some embodiments, package 120 may be similar to, or analogous to, a package of packages 110 as were previously described. Thus, package 120 can be an example of any of the packages present on the substrate surface in FIG. 1A. Similar to the substrate shape, in some embodiments, package 120 may be a rectangular area, but in other embodiments, package 120 may be of any other suitable shape commonly used within electronic device manufacturing systems.

In some embodiments, package 120 can include integrated modules 130A-D, as seen in view 104. Integrated modules 130A-D may be associated with the package and placed according to an intended surface profile template, or a package template. Modules 130A-D may be any kind of integrated electrical modules commonly used in integrated circuits (ICs), video displays, or any such or similar electronic device manufacturing process or combination of such. Such integrated modules may include, but are not limited to, computer memory modules, processor modules, sensors, logic relays, antennas, lens arrays, color filters, light focusing modules, or any other such or similar integrated modules or combination of such, commonly found within electronic device manufacturing systems.

In some embodiments, modules 130A-D may be connected by connection paths 135A-D. Connection paths 135A-D may be electrically conductive paths on the package surface area 122, and correspond to paths from a target template and/or altered template for the surface profile of the package.

In some embodiments, during formation, connection paths 135A-D may be formed through a deposition process, a digital lithography process and/or an etch process. For example, in some embodiments, a first layer of photoresist may be deposited onto a surface area of the package, or substrate (e.g., surface area 122). In some embodiments, the photoresist material may be a positive photoresist material (i.e., where a portion of the photoresist material that is exposed to actinic light becomes soluble to a photoresist developer) or a negative photoresist material (i.e., where a portion of the photoresist material that is exposed to actinic light becomes insoluble to a photoresist developer).

Accordingly, in some embodiments, such an actinic light source and corresponding mask pattern can either correspond to positive photoresist material, and denote patterns (i.e., electrical connection paths) with illumination from the actinic light source. In other embodiments, such components may correspond to negative photoresist material, and denote patterns (i.e., electrical connection paths) with darkness, or lack of illumination.

Thus, after placement of such photoresist material, the package and the substrate may undergo lithographic exposure to precisely remove photoresist material according to a predefined pattern and create a material surface profile pattern that can form a foundation for further creation of electrical connection paths between surface components.

After such a process the package(s) and respective substrate can undergo material deposition, etching, or any other surface altering process in order to place material (e.g., electrically conductive material) into the paths created by the lithographic exposure, so as to create complete connection paths between surface modules and components.

In some embodiments, connection paths (e.g., connection paths 135A-D) may only be partially formed (through lithographic exposure, or otherwise), and at a later time, processing can return to the substrate to complete the connection paths. In such cases, a lithographic exposure process may be to complete, or bridge, the partial connection paths together.

In some embodiments, the material to be placed into the paths is a conductive material (e.g., metal). For example, the conductive material can be molybdenum. After the designated regions of the photoresist material are removed, the now-exposed material can be processed in accordance with the photoresist pattern. For example, wiring can be formed by a material deposition or etching process.

In some embodiments, the connection paths may be made out of any electrically conductive material, including copper, gold, germanium, or any other electrically conductive material commonly used within electronic device manufacturing.

In some embodiments, the respective positions of modules 130A, 130B, 130C, 130D on package 120 are different than intended (e.g., differ from positions indicated in a template). Such differences in positions should be identified and corrected for in order to enable accurate connection paths between the modules 130A, 130B, 130C, 130D. Embodiments described herein cover techniques for identifying differences between planned positions and actual positions of modules 130A, 130B, 130C, 130D of a package 120 and techniques for correcting such differences in a manner that minimizes wait times, maximizes throughput and/or minimizes errors.

FIG. 1C illustrates a top-down view 106 of an integrated module 140 (also referred to as a chip group) of a package on a substrate, in accordance with some embodiments of the present disclosure. In some embodiments, integrated module 140 may be similar, or analogous, to modules 130A-D, and incorporate at least the embodiments discussed therein. As such, module 140 may be any kind of integrated electrical modules (as discussed above) commonly associated with electronic device manufacturing systems.

Integrated module 140 may include a number of connection points 150A-L on the surface area 142 of the integrated module. Such connection points may be designed to be electrically connected to either a connection path, or other connection points on the package surface area. The displacement profile or offset profile shows circles for connection points that are unchanged between original target locations and updated target locations. The displacement profile or offset profile shows arrows indicating a direction and/or magnitude of a shift in position for connection points between original target locations and updated target locations. Each module or chip group may include different shifts and/or rotations that should be captured and used to compute updates to connection points, as shown. This information is used to update a lithographic exposure plan for forming electrical connections between modules or chip groups. One of ordinary skill in the art, having the benefit of this disclosure, will appreciate that such modules may be equipped with many more (or less), or any number of connection points of varying design, shape, placement, and function, and that view 106 of module 140 is exemplary.

Embodiments discuss multiple techniques for performing metrological scanning and lithographic exposure processing in parallel and/or in series, including a through the lens (TTL) method, a first in first out (FIFO) method, or a scan ahead (SA) method. As will be discussed below, by making use of these methods, multiple substrates can be metrologically scanned and/or lithographically exposed in parallel. Thus, process wait and idle times can be reduced, increasing throughput, maximizing efficiency, and capitalizing on available resources. Additionally, errors introduced by additional handling between scanning and lithographic exposure may also be reduced or eliminated in some embodiments.

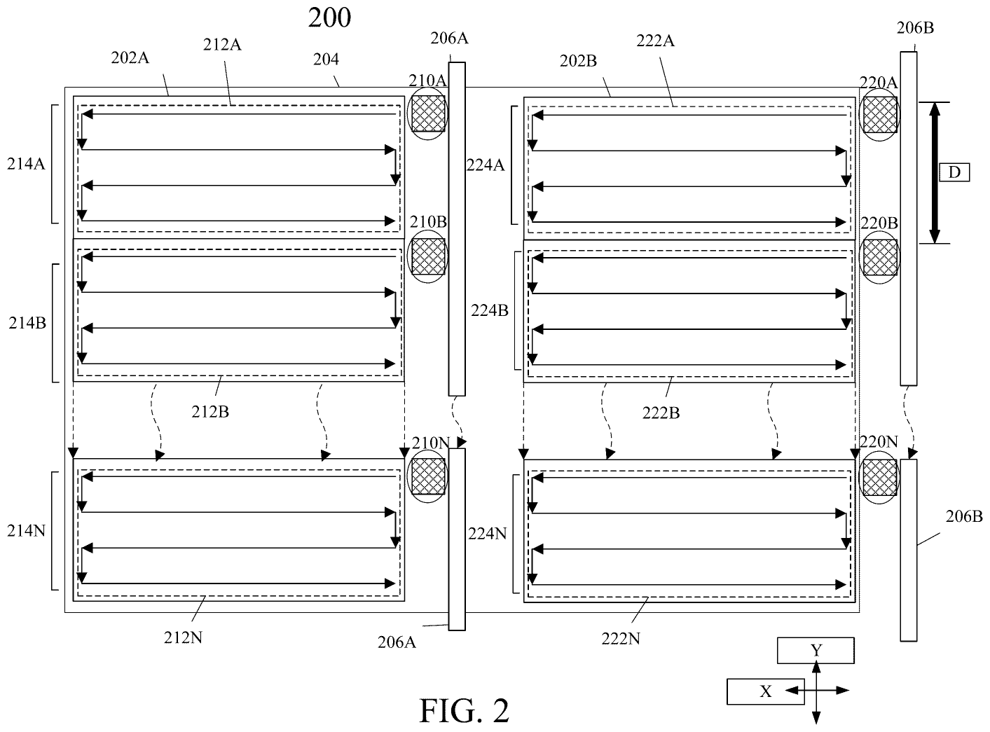

FIG. 2 illustrates a top-down view of a lithographic processing system suitable for performing a TTL method of metrological scanning and lithographic exposure, in accordance with some embodiments of the present disclosure.

As shown, the digital lithography system 200 includes a stage assembly including a base (e.g., a granite base) (not shown from the top-down view), a stage 204 and substrates 202A and 202B disposed on the stage 204. Substrates 202A and/or 202B may be similar, or analogous, to substrates discussed with respect to FIGS. 1A-C, and incorporate at least the embodiments discussed therein. Accordingly, the substrate may be a glass plate, a wafer, a PCB, or any other type or form of substrates commonly used in electronic device manufacturing systems.

In some embodiments, the substrates may be attached, or fixedly coupled, to the stage. In some embodiments, substrates may attach, or fixedly couple, to the stage via suction points that attach to the substrate bottom surface. In other embodiments, other methods of attachment may be used, including mechanically clamping the substrate, holding the substrate in place via physical barriers, vacuum chucking, electrostatic chucking, or any other method or combination of such commonly used techniques of attaching, securing and/or supporting a substrate on a processing stage.

In some embodiments, one, two, or more bridges (e.g., bridges 206A and 206B), may span a Y dimension of the stage 204, and may be spaced a vertical distance above the stage assembly (e.g. in FIG. 2, bridges 206A and 206B rest further in the direction out-of-the-page when compared to the stage 204). In some embodiments, the length of each bridge 206A and 206B can range between about 500 (millimeters) mm and about 1000 mm. For example, the length of each bridge 206A and 206B can be about 750 mm. In some embodiments, each bridge 206A and/or 206B may be spaced a distance of 100 mm above the surface of the of the substrate. In other embodiments, the lengths of each bridge, and the distance of the spacing above the surface of the substrate may be different than above.

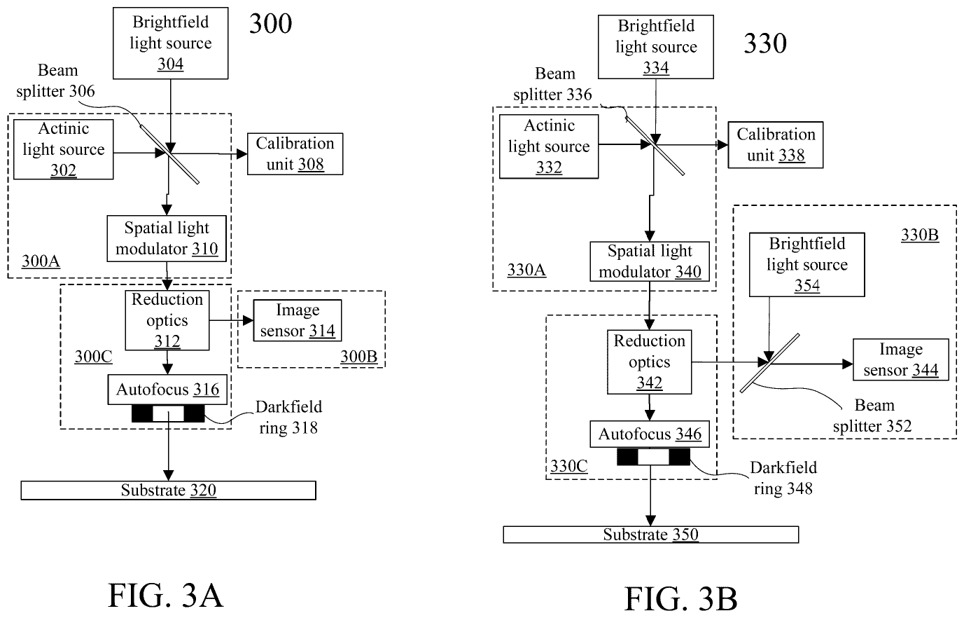

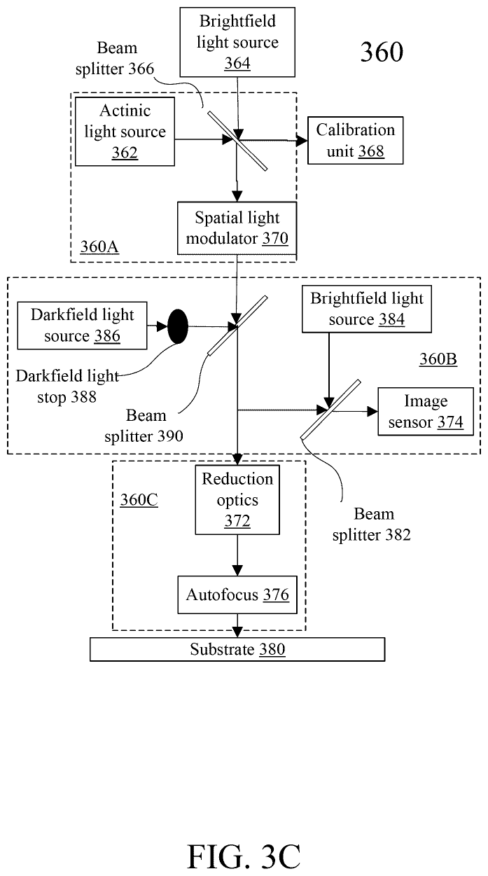

In some embodiments, bridges 206A and 206B can support one or more lithographic processing units (which may include, or incorporate, metrological scanning units, as will be discussed below and further with respect to FIGS. 3A-3C). In some embodiments, lithographic processing units 210A-N and 220A-N may be combination, or combined, lithographic processing units, which are units that combine metrological scanning units and lithographic exposure units capable of both scanning and exposing an area below the unit. Such combined units may share a single optical lens, a single vertical axis, and/or a single housing. Such combined units may operate through a single optical lens, a single vertical axis, and/or a single housing. Thus, the single optical lens, vertical axis, and housing can support both scanning and exposing capabilities. In alternate embodiments, units 210A-N and/or 220A-N may be one type of unit, such as a metrological scanning or a lithographic exposure unit rather than a combined metrological scanning and lithographic exposure unit.

In some embodiments, lithographic processing units 210A-N and 220A-N may be mounted onto bridges 206A and 206B and placed a distance D apart in the Y dimension. In some embodiments, distance D may be between 1 and 10 cm. In some embodiments, distance D may be between 1 and 100 cm.

In some embodiments, processing units 210A-N and 220A-N may be mounted onto bridges 206A and 206B through use of any common mounting or mechanically fastening technique, including screws, nuts and bolts, rivets, pins, nails, staples, welding, press-fitting, clamping, magnets, or any other commonly used method for mounting lithographic processing units in lithography systems.

Each lithographic processing units 210A-N and 220A-N, regardless of the type, may face vertically downward, and perform processes through a lens that faces vertically downward, normal to the stage. In such a way, each lithographic processing units 210A-N and 220A-N may project a projected area, regardless of the type of processing unit (e.g. combination, metrologically scanning or lithographic exposure), normally onto the stage 204 and any substrates on the stage. Each projected area (as seen by each cross-hatched square associated with lithographic processing units 210A-N and 220A-N in FIG. 2) may correspond to a field of view and/or field of projection of the lithographic processing units 210A-N, 220A-N. In some embodiments, a projected area may range from 1 mm by 1 mm to 2 mm by 2 mm. In some embodiments, the projected area may range from 1 mm by 1 mm to 5 mm by 5 mm.

Each lithographic processing units 210A-N and 220A-N may correspond to a processing region (e.g., one of 214A-N and 224A-N) of the substrate, or stage, below it, such that the stage and corresponding substrate surface areas are divided into portions (e.g., equal portions). In some embodiments, the processing regions may be equally distanced and dimensioned rectangular portions of the surface of the substrate. In other embodiments, the processing regions may be any other shape sufficient to facilitate piecewise processing, scanning, and exposure of the substrate.

In some embodiments, the processing regions may cumulatively span the entire surface of a substrate on the stage and/or of multiple substrates on the stage. In other embodiments, the processing regions may only span a portion of a substrate on the stage.

In some embodiments, a computing subsystem may be used with actuators to translate the stage in the denoted x and y directions and pass each projected area of each lithographic processing units 210A-N and 220A-N, over the corresponding processing region of the substrate, or stage, below it.

For example, a computing subsystem associated with the lithographic processing unit may translate the stage in such a way that the projected area of lithographic processing unit 210A is translated over the entire surface area of processing region 214A of substrate 202A. This process is repeated, for the remaining lithographic processing units 210C-N and substrate processing regions 214C-N, and may be performed in parallel in embodiments.

An identical process may occur in parallel with regard to the second substrate 202B on the stage, and its associated processing regions 224A-N and lithographic processing units 220A-N(along with their corresponding projected areas) in embodiments.

In such a way, translation of the stage, and translation of substrates on the stage, may ensure a projected area of at least one lithographic processing unit passes over all of at least one processing region. In such a way, cumulatively, all the surface area of the substrates supported by stage 204 may be processed.

In some embodiments, multiple processing passes, or sequences, may be made, for multiple similar or different processing steps involving the lithographic processing units.

In some embodiments, the stage 204 may translate according to a sequence such that each lithographic processing unit 210A-N and 220A-N may proceed along a specific scan path and scan the processing regions corresponding to a substrate surface. Each lithographic processing unit (and its projected area) may travel along the scan path projected onto the substrate, and so process the processing region or area between it and the adjacent lithographic processing unit.

In a non-limiting example, stage 204 may translate in such a way such that the projected area of lithographic processing unit 210A translates according to path 212A and entirely passes over all of the processing region 214A (i.e. a surface area portion) of substrate 202A. For example, all of the surface area between lithographic processing unit 210A and adjacent lithographic processing unit 210B may be processed. In some embodiments, a rasterized path is followed by lithographic processing units 210A-N. Such translation of multiple projected areas may occur in parallel. For example, the projected area of lithographic processing unit 210B may be made to translate according to path 212B, while unit 210A is translating along path 212A. The projected area of lithographic processing unit 210B may entirely pass over all of the processing region 214B of substrate 202A. otherwise stated, all of the surface area between lithographic processing unit 210B and the next adjacent lithographic processing unit (not show in the images), and so and so forth until similarly, and in parallel, the projected area of the final lithographic processing unit 210N translates according to path 212N and entirely passes over all of the surface area portion 214N of substrate 202A, and reaches the end of the substrate. B

In such a way, and in an embodiment of the lithographic processing system 200, the projected area of each lithographic processing unit of the lithographic processing unit may pass over a corresponding partial area of the substrate, such that cumulatively, and in parallel, the entire surface area of each substrate may be passed over by a projected area of an associated lithographic processing unit.

In some embodiments, substrate 202B may rest on the same movable stage 204 as substrate 202A, and may move in a parallel manner. For example, when stage 204 is translated, both substrates 202A and 202B move together. Each projected area of lithographic processing units 210A-N may translate over the entire surface area of substrate 202A. Each projected area of lithographic processing units 220A-N may translate over each surface area portion 224A-N of substrate 202B. Thus, the entire surface area of both substrates may be passed over by a projected area of an associated lithographic processing unit.

In some embodiments, to avoid abrupt transitions from a first processing region to a second processing region adjacent to the first processing region (either attached to the same bridge or to a different bridge), the lithographic processing unit corresponding to the first processing region can encroach into the second processing region. Similarly, the exposure unit corresponding to the second processing region can encroach into the first processing region. For example, lithographic processing unit 210B can encroach into processing region 214A and/or processing region 214C (not shown in figures), and exposure unit 220B can encroach into processing region 224A and/or processing region 224C. Accordingly, different lithographic processing units 210A-N may have overlapping processing regions.

In some embodiments, stage 204 may translate in a zig-zag movement so as to translate the projected area from each lithographic processing unit onto a substrate in a zig-zag movement that translates the lithographic processing unit projected area in a zig-zag movement over a respective surface area of the substrate. For example, stage 204 may begin the scanning process by translating in the negative X direction until each lithographic processing unit projected area reaches the end of a substrate, according to the first, starting arrow of scan paths 212A-N and 222A-N. Then, the stage may translate slightly in the Y direction, driving the lithographic processing unit projected areas in the negative Y direction according to the second arrows in the scan paths 212A-N and 222A-N. The stage may continue movement in this manner until each projected area of lithographic processing units has completed an associated scan path across an associated surface area. Thus, the scan paths as seen in FIG. 2 may procedurally, in parallel, and in a zig-zag manner, scan the entire surface of substrates 202A and 202B.

In some embodiments, the scan paths may follow a different pathway. In a singular example, in some embodiments, scan path 212A may translate in shortening concentric paths around the exterior of processing region 214A, until it reaches the center, all of processing region 214A has been concentrically scanned.

In other embodiments, the scan paths may zig-zag in a manner orthogonal to the embodiment shown in FIG. 2. For example, the stage may first move in the negative Y direction until a path reaches the end of the substrate. After, the stage may move slightly in the positive X direction. After, the stage may move until the end of the substrate entirely in the positive Y direction, and so on and so forth. One of ordinary skill in the art, having the benefit of this disclosure will be able to design any number of scan paths that operate in different manners than shown in FIG. 2, but that continue to accomplish the goal of processing the entire surface area of each substrate, by passing over the entire substrate surface area at least once by the projected area of a lithographic processing unit.

In some embodiments, more (or less) lithographic processing units may be used along each bridge, effectively shortening (or lengthening) the distance D between adjacent lithographic processing units. In some embodiments, this may diminish (or increase) the surface area to be passed over by each respective projected area of each lithographic processing unit. This may therefore shorten (or lengthen) the time for the lithographic processing system to pass over the entire surface area of each substrate.

In other embodiments, more (or in some cases less) than two substrates may be input into the system.

In some embodiments, the stage, and the bridge, may be lengthened in the Y direction to accommodate more substrates and/or more lithographic processing units to process additional substrates in parallel. In some embodiments, the stage may be lengthened, and further bridges and lithographic processing units may be added in the X direction. Thus, a variety of configurations, to incorporate more (or less) than two substrates, and process them in parallel, may be applied to the lithographic processing system. One of ordinary skill in the art, having the benefit of this disclosure, will be able to design a lithographic processing system that processes more than two, or any number of substrates, of any dimensions, in parallel according to the above method.

As discussed above, in some embodiments, the lithographic processing units can be combined lithographic processing units (as will be discussed further with respect to FIGS. 3A-C) that incorporate both metrological scanning and lithographic exposure portions.

In such embodiments, this can facilitate processing a substrate. For example, a first substrate may be placed onto the stage (e.g., the portion of the stage occupied by substrate 202A or substrate 202B). After, the stage may be translated according to a first sequence (e.g., such that the projected areas travel along scan paths 212A-N and 222A-N) such that the combined lithographic processing units capture data reflective of the entire surface profile of the substrate. A computing subsystem can then recognize any errors and deviations within the data reflecting differences between the surface profile and an intended substrate surface profile (e.g., according to a substrate surface profile template, or a substrate surface profile exposure pattern). The computing subsystem can then determine remedial updates for the intended surface profile, and apply the updates to the intended surface profile template (e.g., intended exposure pattern), so as to correctly form connections and patterns. In such a way, the lithographic processing system may overcome any real errors and offsets within the surface profile of the substrate. The processing system can then perform a second translation according to a second sequence and lithographically expose the surface profile of the substrate according to remedially updated template (or updated exposure pattern). In embodiments, the substrate remains secured at the same region of the stage during both scanning and lithographic exposure, and is not moved between scanning and lithographic exposure. Accordingly, any errors that might be introduced in moving the substrate between scanning and lithographic exposure may be eliminated.

By combining lithographic exposure portions and metrological scanning portions within one processing unit, the unit may be calibrated once, to enable two different calibrated processes.

Furthermore, the lithographic processing system can perform metrological scanning and exposure without movement of the substrate. This can serve to limit errors and offsets that can be introduced when a substrate is moved from one processing area to the next.

In some embodiments, the process(es) described with respect to FIG. 2 can be applied in parallel to 2, or 4, or any further number of substrates that the stage and lithographic units are designed to support and process.

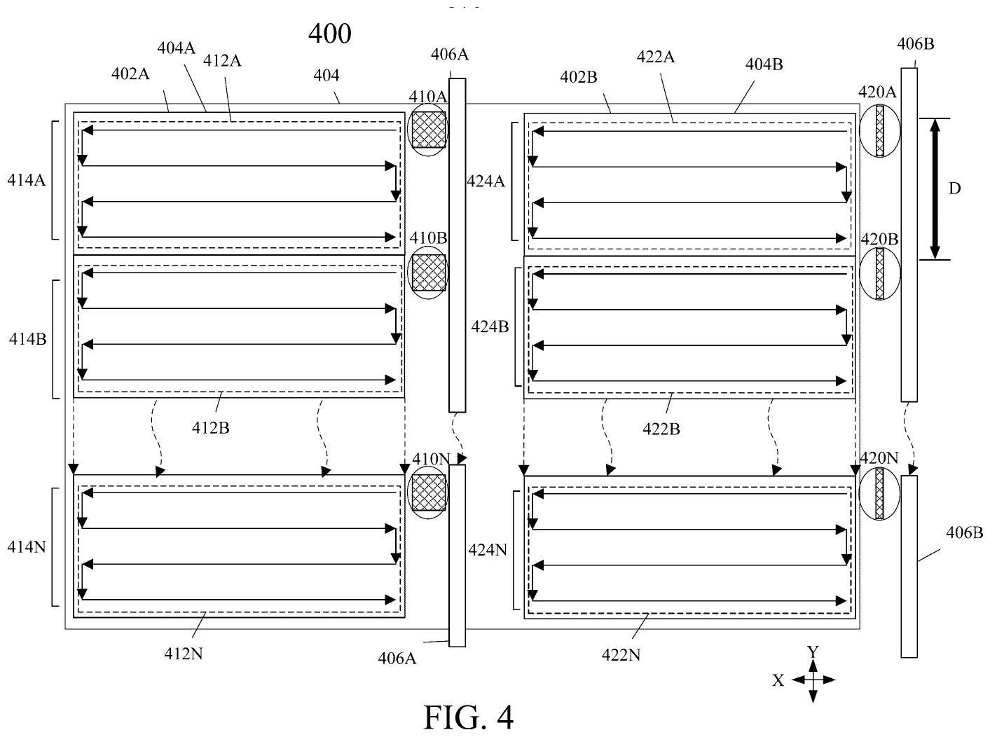

In some embodiments, the lithographic processing system may have lithographic exposure units and metrological scanning units that are separate. An example of such an embodiment is shown in FIG. 4. In some embodiments, metrological scanning units can be separated by being attached to different bridges. For example, in the embodiment seen in FIG. 2, bridge 206A may hold scanning units and bridge 206B may hold exposure units (in some cases this may be reversed).

In such a configuration, metrological scanning and lithographic exposure may be done piecewise, with an unprocessed substrate first being placed in the portion of the processing unit for metrological scanning (e.g., the portion where substrate 202A is placed with respect to FIG. 2). After the system has translated and scanned the surface profile of the substrate, the substrate can be physically removed and placed in the next location on the stage for lithographic exposure (e.g., the portion where substrate 202B is placed with respect to FIG. 2). While the substrate is undergoing lithographic exposure, another substrate placed at the first location may undergo scanning in parallel to the first substrate undergoing lithographic exposure. Both substrates may be secured to a same stage, and may be moved together for parallel processing, in some embodiments.

In some embodiments, remedial updates for the substrate, determined based on the data captured during the scanning, can be applied to an exposure template as the substrate is being moved.

In some embodiments, the above process can be performed with multiple substrates such that while a substrate is being metrologically scanned, a previously scanned substrate is being lithographically exposed. The substrates can then be removed, with the scanned substrate being moved to the portion of the stage for lithographic exposure. A new, unprocessed substrate can then be placed on the portion of the stage for metrological scanning. In such a way, processing may be done in parallel, and throughput can be increased.

In some embodiments, more than two substrates may be simultaneously processed. For example, the portion of the stage for metrological scanning may hold two, three, or any number of substrates that can be scanned in parallel, and after, the two, three, or any number of substrates that have been scanned can be moved to the lithographic exposure portion of the stage (which may also support multiple substrate for simultaneous processing). In such a way, multiple substrates (any number greater than one) can be exposed, and scanned, in parallel.

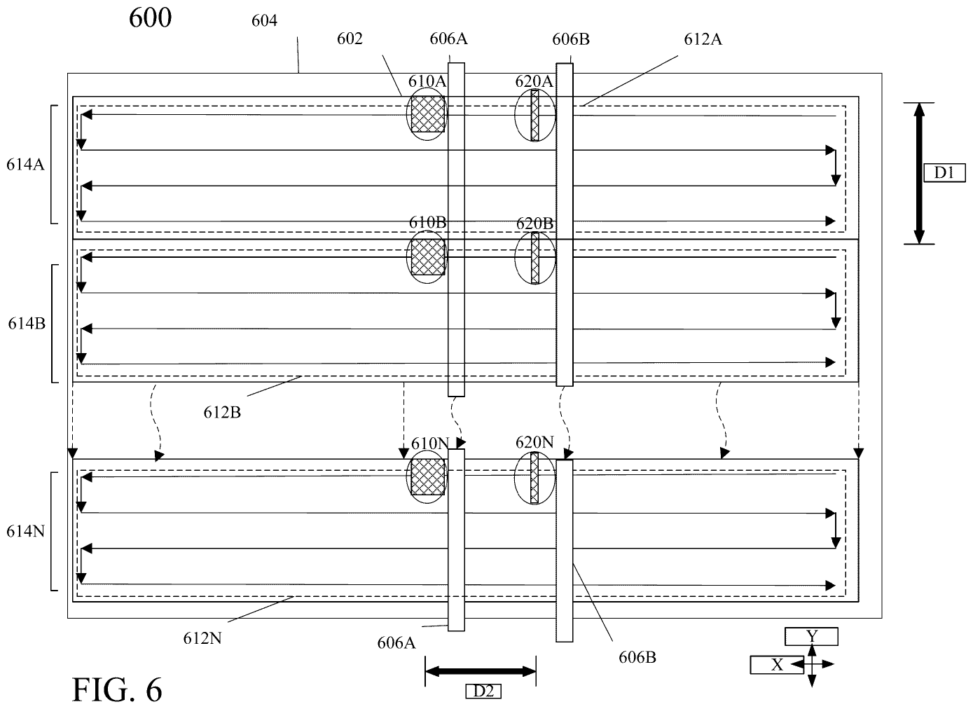

In some embodiments, the lithographic processing system may have lithographic exposure units and metrological scanning units that are separate but placed on the same bridge, and offset by a smaller distance. An example of such an embodiment is shown in FIG. 6. For example, with respect to the embodiment seen in FIG. 2, scanning units and exposure units can be attached to the same bridge 206A, with exposure units in a linear configuration with respect to the Y axis (e.g. all exposure units may be attached to the right side of the bridge 206A), while the scanning units may also be in a linear configuration with respect to the y axis, but may be offset from the exposure units (e.g. all the scanning units may be attached to the left side of the bridge 206A).

Such an offset can serve to give the scanning units time to scan, and a computing subsystem time to process remediations, before the exposure units expose the substrate surface, as translation is occurring. In such embodiments, the stage may only translate once. During the one-time translation, scanning, remediation processing, an exposure can occur. For example, while the scanning unit is capturing measurement data, the computing subsystem may be determining offsets and updating a target template for the surface profile. While this is happening, exposure units can be exposing portions of the substrate that have already been passed over. Thus, all processes can be accomplished in the same translational sequence.

FIG. 3A illustrates a combined lithographic unit 300, in accordance with some embodiments of the present disclosure. Combined lithographic unit 300 (as may be referenced by 210A-N and 220A-N in FIG. 2) includes a lithographic exposure portion 300A, a metrological scanning portion 300B, a focusing portion 300C, and a calibration portion including a brightfield light source 304 and a calibration unit 308.

In some embodiments, the combined lithographic unit 300 includes an image sensor 314 for generating images of substrates. Image sensor 314 may be associated with brightfield (BF) microscopy or darkfield (DF) microscopy.

In some embodiments, lithographic exposure portion 300A can include an actinic light source 302, and a spatial light modulator 310. Actinic light source 302 can be any type of actinic light source (e.g., an ultraviolet (UV) or visible light source) capable of inducing a photochemical reaction. Actinic light source 302 may be, for example, a mercury vapor lamp, a fluorescent lamp, a metal halide lamp, a light emitting diode (LED), a laser, or any other type of lamp, bulb, diode, or other actinic light sources commonly used within electronic device manufacturing.

According to some embodiments, spatial light modulator (SLM) 310 may be a digital micromirror device (DMD) of any type (e.g. a DMD device making use of deformable micromirrors, actuating micromirrors, etc.), a liquid crystal (LC) SLM, an optical phase array, or any other kind of SLM commonly used within electronic device manufacturing.

As seen in FIG. 3A, lithographic exposure portion 300A may combine with other portions of the unit via a beam splitter 306. In some embodiment, beam splitter is a polarizing beam splitter. Brightfield light source 304 and actinic light source 302 may direct light to beam splitter 306. Light from actinic light source 302 may reflect off of beam splitter 306 to spatial light modulator 310. Light from brightfield light source 304 may pass through beam splitter 306 to spatial light modulator 310 in embodiments. In embodiments, at least some light from brightfield light source 304 is reflected off of beam splitter 306 towards calibration unit 308.

As seen in FIG. 3A, lithographic exposure portion 300A may include an actinic light source 302 and a spatial light modulator 310. However, one of ordinary skill in the art, having the benefit of this disclosure, will be able to design a lithographic exposure portion including more (or fewer) components to accomplish a similar task as the one disclosed.

In some embodiments, scanning portion 300B can include an image sensor 314. In some embodiments, such an image sensor may be a complementary metal-oxide-semiconductor (CMOS) sensors including a Seiwa BG160M integrated camera, a GigE integrated Camera BG series, a Toshiba BG160MCF integrated camera, or a Seiwa BG505LMCG/LMCF, or any other CMOS style integrated camera commonly used in electronic device manufacturing and imaging systems. In some embodiments, one or more sensing elements may be any one of a different type of sensor, including charge-coupled device (CCD) sensor, an active-pixel sensor, an infrared (IR) sensor, including a Multispectral and Hyperspectral Sensor, a LIDAR Sensor, or any other kind of imaging sensor commonly used in electronic device manufacturing and imaging systems.

In some embodiments, focusing portion 300C can include reduction optics (e.g. reduction optics 312), one or more autofocus element (e.g., autofocus element 316), and one or more darkfield ring (e.g., darkfield ring 318).

In some embodiments, reduction optics may be employed to reduce the dimensions of projected and received image patterns. In some embodiments, the reduction optics employed may use a variety of lenses, including compound lenses, lens assemblies, and/or optical trains.

In some embodiments the reduction optics may include one or more lenses of a high-resolution and a fixed focal length. In some embodiments the lens may be intended for machine vision. In some embodiments, the lens may be a machine vision lens such as the Seiwa STV-3518-T3, or other similar lenses, or any other kind or brand of similar lens commonly used in electronic manufacturing systems and imaging systems.

In some embodiments, an autofocus (AF) 316 is included. Autofocus 316 may serve to autofocus the projected and received image, so as to increase the image sharpness.

In some embodiments, focusing portion 300C may include a darkfield ring 318. In some embodiments, the darkfield ring 318 may be selectively engaged during operation of the system. In some embodiments, the darkfield ring 318 may be exterior of the unit, and may be any type of darkfield ring typically used in electronics device manufacturing systems, or darkfield microscopy systems, or both.

As seen in FIG. 3A, in some embodiments, the scanning portion and exposure portion may share the same focusing portion 300C to scan or expose a substrate (e.g., substrate 320). In such a way, calibration of the focusing portion may be performed once to affect both the exposure portion 300A and scanning portion 300B.

In some embodiments, scanning portion 300B and exposure portion 300A may share a common vertical axis. In other embodiments, scanning portion 300B and exposure portion 300A may have varying axes. In some embodiments, scanning portion 300B and exposure portion 300A may be within separate units, and lithographic exposure unit 300 may be two units.

According to some embodiments, calibration may be performed via the calibration unit 308 and brightfield light source 304. Brightfield light source 304 may be an appropriate light source.

In some embodiments, during a scanning phase, the combined unit 300 may engage only the scanning portion of the unit. In some embodiments, during an exposure phase, the combined unit 300 may engage only the exposure portion 300A of the unit.

In some embodiments, when the scanning portion is engaged, image sensor 314 may capture image (e.g., scanning) data from substrate 320. Illuminating light from brightfield light source 304 may transmit through the exposure portion unmodified. The illuminating light may pass through reduction optics, 312, autofocus 316, and darkfield ring 318, to reach substrate 320. Light that strikes the substrate may be reflected back, through the autofocus, through the reduction optics, and deliver surface data to image sensor 314. In some embodiments, reduction optics 312 may include a beam splitter (not shown) to direct the reflected illuminating light to image sensor 314. In such a way, surface data can be captured from a substrate using brightfield illumination.

In some embodiments, the bright field light source may not be engaged, and instead the dark field ring 318 may provide illuminating light to substrate 320. Illuminating light from the darkfield ring may strike the substrate. In a similar manner as described above, the illuminating light may reflect from the substrate and be directed to image sensor 314. In such a way, surface data can be captured from a substrate using darkfield illumination.

When the exposure portion is engaged, actinic light from the actinic light source 302 may be reflected via beam splitter 306 to SLM 310. SLM 310 may impose the target (e.g., intended) template onto the actinic light source, such that the actinic light includes an exposure pattern or template. The actinic light may continue through reduction optics 312 and autofocus 316, and darkfield ring 318 to strike substrate 320. In such a way, a target exposure template can be applied to a substrate using an actinic light source.

FIG. 3B illustrates a combined lithographic unit 330, in accordance with some embodiments of the present disclosure. Combined lithographic unit 330 (as may be referenced by 210A-N and 220A-N in FIG. 2) includes a lithographic exposure portion 330A, a metrological scanning portion 330B, a focusing portion 330C, and a calibration portion including a brightfield light source 334 and a calibration unit 338.

In some embodiments, the combined lithographic unit 330 includes an image sensor 344 for generating images of substrates. Image sensor 344 may be associated with brightfield (BF) microscopy or darkfield (DF) microscopy.

In some embodiments, lithographic exposure portion 330A can include an actinic light source 332, and a spatial light modulator 340. Actinic light source 332 can be any type of actinic light source (e.g., a UV or visible light source) capable of inducing a photochemical reaction. In some embodiments, actinic light source 332 can be or include any of the components and/or methods described with respect to actinic light source 302 in FIG. 3A, and incorporate and/or augment at least the embodiments described therein.

According to some embodiments, spatial light modulator (SLM) 340 may be a digital micromirror device (DMD) of any type (e.g. a DMD device making use of deformable micromirrors, actuating micromirrors, etc.). In some embodiments, SLM 340 can be or include any of the components and/or methods described with respect to SLM 310 of FIG. 3A, and incorporate and/or augment at least the embodiments described therein.

As seen in FIG. 3B, lithographic exposure portion 330A may combine via the other portions of the unit via a beam splitter 336. In some embodiments, beam splitter 336 is a polarizing beam splitter. Brightfield light source 334 and actinic light source 332 may direct light to beam splitter 336. Light from actinic light source 332 may reflect off of beam splitter 336 to spatial light modulator 340. Light from brightfield light source 334 may pass through beam splitter 336 to spatial light modulator 340 in embodiments. In embodiments, at least some light from brightfield light source 334 is reflected off of beam splitter 336 towards calibration unit 338.

As seen in FIG. 3B, lithographic exposure portion 330A may include an actinic light source 332, and a spatial light modulator 340. However, one of ordinary skill in the art, having the benefit of this disclosure, will be able to design a lithographic exposure portion including more (or fewer) components to accomplish a similar task as the one disclosed.

In some embodiments, scanning portion 330B can include an image sensor 344. In some embodiments, such an image sensor may be any CMOS style integrated camera commonly used in electronic device manufacturing and imaging systems. In some embodiments, one or more sensing elements may be any other kind of imaging sensor commonly used in electronic device manufacturing and imaging systems. In some embodiments, image sensor 344 can be or include any of the components and/or methods described with respect to image sensor 314 in FIG. 3A, and incorporate and/or augment at least the embodiments described therein.

In some embodiments, scanning portion 330B may include a secondary brightfield light source 354 and a corresponding beam splitter 352. Beam splitter 352 may be a polarized beam splitter. Beam splitter 352 may direct light from brightfield light source 354 to reduction optics 342. Light from reduction optics 342 may pass through beam splitter 352 to reach image sensor 344, in some embodiments.

In some embodiments, the combined lithographic unit 330 can include two brightfield sources, one before and affected by the SLM and one unaffected by the SLM. In some embodiments, this may serve to introduce less noise into the projected image.

In some embodiments, focusing portion 330C can include reduction optics (e.g. reduction optics 342), autofocus element (e.g., autofocus element 346), and darkfield ring (e.g., darkfield ring 348). In some embodiments, the reduction optics, autofocus, and darkfield ring of FIG. 3B may be positioned in a similar manner as was described with respect to the reduction optics, autofocus, and darkfield ring of FIG. 3A, and incorporate and/or augment at least the embodiments described therein. In some embodiments, the reduction optics, autofocus, and darkfield ring of FIG. 3B may include or may be similar components as were described with respect to the reduction optics, autofocus, and darkfield ring of FIG. 3A, and incorporate and/or augment at least the embodiments described therein.

Similar to the disclosure with respect to FIG. 3A, in some embodiments, the scanning portion and exposure portion of FIG. 3B may share the same focusing portion to scan or expose a substrate (e.g., substrate 350). In such a way, calibration of the focusing portion may only need to be performed once to affect both the exposure portion 330A and scanning portion 330B.

In some embodiments, scanning portion 330B and exposure portion 330A may share a common vertical axis. In other embodiments, scanning portion 330B and exposure portion 330A may have varying axes. In some embodiments, scanning portion 330B and exposure 330A may be within separate units, and lithographic exposure unit 300 may be two units.

According to some embodiments, calibration may be performed via the calibration unit 338 and brightfield light source 334. Brightfield light source 334 may be any appropriate light source.

In some embodiments, during a scanning phase, the combined unit 330 may engage only the scanning portion of the unit. In some embodiments, during an exposure phase, the combined unit 330 may engage only the exposure portion of the unit.

In some embodiments, when the scanning portion is engaged, image sensor 344 may capture image (e.g., surface) data from substrate 350. Illuminating light from brightfield light source 334, brightfield light source 354, or a combination of the two can be used.

In some embodiments, illuminating light from brightfield light source 334 may transmit through the exposure portion unaffected. The illuminating light may then pass through reduction optics 342, autofocus 346, and darkfield ring 348, to reach substrate 350. Light that strikes the substrate may be reflected back, through the autofocus, through the reduction optics, through beam splitter 352, and deliver surface data to image sensor 344. In some embodiments, reduction optics 342 may include a beam splitter (not shown) to direct the reflected illuminating light to image sensor 344. In such a way, surface data can be captured from a substrate using brightfield illumination.

In some embodiments, illuminating light from brightfield light source 354 may be directed to reduction optics 342 via beam splitter 352. This light may transmit through reduction optics 342, autofocus 346, and darkfield ring 348, to reach substrate 350. Light that strikes the substrate may be reflected back, through the autofocus, through the reduction optics, through beam splitter 352, and deliver surface data to image sensor 344. In some embodiments, reduction optics 342 may include a beam splitter (not shown) to direct the reflected illuminating light to image sensor 344. In such a way, surface data can be captured from a substrate using brightfield illumination.

In some embodiments, the brightfield light sources may not be engaged, and instead the darkfield ring 348 may provide illuminating light to substrate 350. Illuminating light from the darkfield ring may strike the substrate. In a similar manner as described above, the illuminating light may reflect from the substrate and be directed to image sensor 344. In such a way, surface data can be captured from a substrate using darkfield illumination.

When the exposure portion is engaged, actinic light from the actinic light source 332 may be reflected via beam splitter 336 to SLM 340. SLM 340 may impose the target (e.g., intended) template onto the actinic light source, such that the actinic light includes an exposure pattern or template. The actinic light may continue through reduction optics 342, autofocus 346, and darkfield ring 348 to strike substrate 350. In such a way, a target exposure template can be applied to a substrate.

FIG. 3C illustrates a combined lithographic unit 360, in accordance with some embodiments of the present disclosure. Combined lithographic unit 360 (as may be referenced by 210A-N and 220A-N in FIG. 2) includes a lithographic exposure portion 360A, a metrological scanning portion 360B, a focusing portion 360C, and a calibration portion including a brightfield light source 364 and a calibration unit 368.

In some embodiments, the combined lithographic unit 360 includes an image sensor 374 for generating images of substrates. Image sensor 374 may be associated with brightfield (BF) microscopy or darkfield (DF) microscopy.

In some embodiments, lithographic exposure portion 360A can include an actinic light source 362, and a spatial light modulator 370. Actinic light source 362 can be any type of actinic light source (e.g., a UV or visible light source) capable of inducing a photochemical reaction. In some embodiments, actinic light source 362 can be or include any of the components and/or methods described with respect to actinic light source 302 in FIG. 3A, and incorporate and/or augment at least the embodiments described therein.

According to some embodiments, spatial light modulator (SLM) 370 may be a digital micromirror device (DMD) of any type (e.g. a DMD device making use of deformable micromirrors, actuating micromirrors, etc.). In some embodiments, SLM 370 can be or include any of the components and/or methods described with respect to SLM 310 of FIG. 3A, and incorporate and/or augment at least the embodiments described therein.

As seen in FIG. 3C, lithographic exposure portion 360A may combine via the other portions of the unit via a beam splitter 366. In some embodiments, beam splitter 366 is a polarizing beam splitter. Brightfield light source 364 and actinic light source 362 may direct light to beam splitter 366. Light from actinic light source 362 may reflect off of beam splitter 366 to spatial light modulator 370. Light from brightfield light source 364 may pass through beam splitter 366 to spatial light modulator 370 in embodiments. In embodiments, at least some light from brightfield light source 364 is reflected off of beam splitter 366 towards calibration unit 368.

As seen in FIG. 3C, lithographic exposure portion 360A may include an actinic light source 362, and a spatial light modulator 370. However, one of ordinary skill in the art, having the benefit of this disclosure, will be able to design a lithographic exposure portion including more (or fewer) components to accomplish a similar task as the one disclosed.

In some embodiments, scanning portion 360B can include an image sensor 374. In some embodiments, such an image sensor may be any CMOS style integrated camera commonly used in electronic device manufacturing and imaging systems. In some embodiments, one or more sensing elements may be any other kind of imaging sensor commonly used in electronic device manufacturing and imaging systems. In some embodiments, image sensor 374 can be or include any of the components and/or methods described with respect to image sensor 314 in FIG. 3A, and incorporate and/or augment at least the embodiments described therein.

In some embodiments, scanning portion 360B may include a secondary brightfield light source 384 and a corresponding beam splitter 382. In some embodiments, secondary bright field source 384 and corresponding beam splitter 382 can function in a similar manner and including similar components as were described with respect to FIG. 3B, and incorporate and/or augment at least the embodiments described therein. Beam splitter 382 may be a polarized beam splitter. Beam splitter 382 may direct light from brightfield light source 384 to reduction optics 372. Light from reduction optics 372 may pass through beam splitter 382 to reach image sensor 374, in some embodiments.

In some embodiments, scanning portion 360B may include an internal darkfield light source 386 and a corresponding darkfield light stop 388 and beam splitter 390, light source 384 and a corresponding beam splitter 382. In some embodiments, the darkfield light stop 388 may be any form of commonly used darkfield lights stop. In some embodiments the darkfield light stop may be a circle of opaque material, capable of blocking the center of illuminating light emitted from darkfield light source 386. In some embodiments, beam splitter 390 may be a polarized beam splitter. Beam splitter 390 may direct light from darkfield light source 386 to reduction optics 372. Light from reduction optics 372 may pass through beam splitter 390, in some embodiments.

In some embodiments, this internally generating the darkfield image may serve to introduce less noise into the projected image. In some embodiments, the combined lithographic unit 330 can include two brightfield sources, one before and affected by the SLM and one unaffected by the SLM. In some embodiments, this may serve to introduce less noise into the projected image.

In some embodiments, focusing portion 360C can include reduction optics (e.g. reduction optics 372) and autofocus element (e.g., autofocus element 376). In some embodiments, the reduction optics and autofocus of FIG. 3C may be positioned in a similar manner as was described with respect to the reduction optics and autofocus of FIG. 3A, and incorporate and/or augment at least the embodiments described therein. In some embodiments, the reduction optics and autofocus of FIG. 3C may include or may be similar components as were described with respect to the reduction optics and autofocus of FIG. 3A, and incorporate and/or augment at least the embodiments described therein.

Similar to the disclosure with respect to FIG. 3A, in some embodiments, the scanning portion and exposure portion of FIG. 3C may share the same focusing portion 300C to scan or expose a substrate (e.g., substrate 380). In such a way, calibration of the focusing portion may only need to be performed once to affect both the exposure portion 360A and scanning portion 360B.

In some embodiments, scanning portion 360B and exposure portion 360A may share a common vertical axis. In other embodiments, scanning portion 360B and exposure portion 360A may have varying axes. In some embodiments, scanning portion 360B and exposure portion 360A may be within separate units, and lithographic exposure unit 360 may be two units.

According to some embodiments, calibration may be performed via the calibration unit 368 and brightfield light source 364. Brightfield light source 364 may be an appropriate light source.

In some embodiments, during a scanning phase, the combined unit 360 may engage only the scanning portion of the unit. In some embodiments, during an exposure phase, the combined unit 360 may engage only the exposure portion of the unit. In some embodiments, when the scanning portion is engaged, image sensor 374 may capture image (e.g., surface) data from substrate 380. Illuminating light from brightfield light source 364, brightfield light source 384, or a combination of the two can be used.

In some embodiments, illuminating light from brightfield light source 364 may transmit through the exposure portion unaffected. The illuminating light may then pass through beam splitter 390, reduction optics 372, and autofocus 376, to reach substrate 380. Light that strikes the substrate may be reflected back, through the autofocus, through the reduction optics, through beam splitter 382, and deliver surface data to image sensor 374. In some embodiments, scanning portion 360B may include a beam splitter (not shown) to direct the reflected illuminating light to beam splitter 382 and image sensor 374. In such a way, surface data can be captured from a substrate using brightfield illumination.

In some embodiments, illuminating light from brightfield light source 384 may be directed to reduction optics 372 via beam splitter 382. This light may transmit through reduction optics 372, and autofocus 376, to reach substrate 380. Light that strikes the substrate may be reflected back, through the autofocus, through the reduction optics, through beam splitter 382, and deliver surface data to image sensor 374. In some embodiments, scanning portion 360B may include a beam splitter (not shown) to direct the reflected illuminating light to beam splitter 382 and image sensor 374. In such a way, surface data can be captured from a substrate using brightfield illumination.

In some embodiments, the brightfield light sources may not be engaged, and instead an internal darkfield light source 386 may provide illuminating light to substrate 380. Illuminating light from the darkfield light source may pass through a darkfield light stop 388, to generate a darkfield illuminating light. This light may be reflected by beam splitter 390, through reduction optics 372, autofocus 376, and may strike the substrate. In a similar manner as described above, the darkfield illuminating light may reflect from the substrate and be directed to image sensor 374. In such a way, surface data can be captured from a substrate using darkfield illumination.

When the exposure portion is engaged, actinic light from the actinic light source 362 may be reflected via beam splitter 366 to SLM 370. SLM 370 may impose the target (e.g., intended) template onto the actinic light source, such that the actinic light includes an exposure pattern or template. The actinic light may continue through beam splitter 390, reduction optics 372, and autofocus 376, to strike substrate 380. In such a way, a target exposure template can be applied to a substrate.

One of ordinary skill in the art, will appreciate that multiple such combinations of combined scanning and exposure units may be envisioned, given the aid of the current disclosure. The designs within FIG. 3A-C may be manipulated into many similar permutations. For example, a single unit may include any number of internal, or external, brightfield light sources, as well as any number of internal, or external darkfield light sources. Such illuminating components, and strategies can be used in any combination to generate surface data from for a substrate.

Turning now to FIG. 4, as was discussed above, in some embodiments of a lithographic system, the scanning portions and exposure portions and systems may not be combined, and may have varying axes or be different units. In an illustration of one such embodiment, FIG. 4 illustrates a top-down view of a lithographic processing system 400, in accordance with some embodiments of the present disclosure.

In some embodiments, the lithographic processing system 400 may have lithographic exposure units 420A-N and metrological scanning units 410A-N that are separate. In some embodiments, metrological scanning units 410A-N can be separate from exposure units 420A-N by being attached to different bridges. For example, scanning units 410A-N can be attached to bridge 406A, while exposure units 420A-N may be attached to bridge 406B (in some cases this may be reversed).

Although system 400 incorporates distinctions from system 200 (as described in FIG. 2), many similarities may exist between the systems. For example, such systems may incorporate similar styles or embodiments of projected areas, one or more similar substrates, processing areas, bridges, stages, etc. Furthermore, such a system may translate the stage, perform metrological scanning, perform template remediation, perform lithographic exposure, and generally perform these and other functions, or combinations of such functions, in a similar manner as was described with respect to FIG. 2. Accordingly, components and functions of system 400 that include similarities to components and functions of system 200 (as were discussed with respect to FIG. 2), may be interpreted as similar, or analogous, and incorporate and augment at least the embodiment discussed therein, mutatis mutandis.

In the embodiment of FIG. 4, system 400 may perform metrological scanning and lithographic exposure in a piecewise manner. To begin, an unprocessed substrate (e.g., substrate 402A) may first be placed in the portion of the processing unit for metrological scanning (e.g., portion 404A). The system may translate and scan the surface profile of the substrate through scanning units 410A-N, processing areas 414A-N, and scan paths 412A-N (in some embodiments, in a similar manner as discussed with respect to FIG. 2, and through similar components as described therein). After scanning, scanning data can be sent to a computing subsystem for remediation processing. The computing subsystem may take such data and produce an update exposure template. Anytime after scanning, the scanned substrate can then be physically removed and placed in the next location on the stage for lithographic exposure (e.g., portion 404B), and be similarly processed through exposure units 420A-N, processing areas 424A-N, and scan paths 422A-N. As discussed previously, such a system 400 may translate, scan, remediate, expose, and generally perform functions similarly, or analogous, to system 200 (as were discussed with respect to FIG. 2) and in such cases incorporate at least the embodiment discussed therein, mutatis mutandis.

In some embodiments, while one or more first substrates are processed by metrological scanning units 410A-N, one or more second substrates are processed in parallel by lithographic exposure units 420A-N. In embodiments, one or more substrates to be scanned and one or more substrates to undergo lithographic exposure are mounted to a same stage, and are processed in parallel. By using a single stage, a number of components for the system may be reduced, decreasing a cost of the system. Once one or more first substrates are scanned by metrological scanning units 410A-N and one or more second substrates have undergone lithographic exposure by lithographic exposure units 420A-N, the one or more second substrates may be removed, the one or more first substrates may be moved to positions formerly occupied by the one or more second substrates, and one or more third substrates that have not yet undergone scanning or lithographic processing may be placed in positions formerly occupied by the one or more first substrates. In this manner at any given time scanning and lithographic exposure may be performed in parallel.

In some embodiments, a substrate transfer mechanism, such as a robot, or human operator, etc. can translate and fix substrates to and from portions 404A and 404B.

In some embodiments, stage 404 and portions 404A and 404B may move together, such that a first substrate 402A may be processed (e.g., scanned) in parallel to a second substrate 402B being exposed.

In some embodiments, such a system can be expanded to process more substrates in parallel. For example, in some embodiments, the stage, and the bridge, may be lengthened in the Y direction to accommodate more substrates and/or more lithographic processing units to process additional substrates in parallel. In some embodiments, the stage may be lengthened, and further bridges and lithographic processing units may be added in the X direction. Thus, a variety of configurations, to incorporate more (or less) than two substrates, and process them in parallel, may be applied to the lithographic processing system. One of ordinary skill in the art, having the benefit of this disclosure, will be able to design a lithographic processing system that processes more than two, or any number of substrates, of any dimensions, in parallel according to the above method.

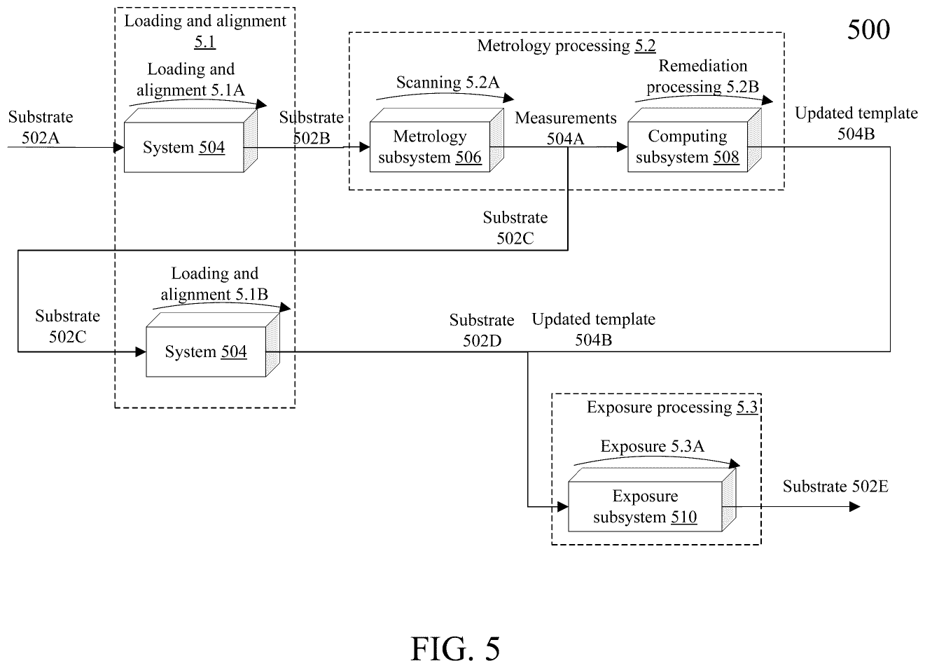

FIG. 5 illustrates an example process flow of a substrate through the system of FIG. 4, in accordance with some embodiments of the present disclosure.

In some embodiments, process 500 of FIG. 5, may use the system 400 of FIG. 4. Accordingly, in some embodiments, process 500 may include methods and components similar to, or analogous to, processes and components of FIG. 4, and include at least the embodiments discussed therein with respect to the components of FIG. 4. Such similar methods and components may include the system 504 (similar or analogous to system 400), metrology subsystem 506 (similar, analogous to, or incorporating scanning units 410A-N), remediation processing 5.2B (not labeled, but described, in FIG. 4), and/or exposure subsystem 510 (similar, analogous to, or incorporating exposure units 420A-N).

Process 500 may begin with loading and alignment (operation 5.1). In such an operation, a system 504 may load and align to a substrate 502A onto a first portion of a stage for processing (e.g., scanning). In some cases a substrate may be loaded onto a stage (manually, via a robot, etc.). After the substrate is loaded, operation 5.1 may capture pre-known locations of the substrate, while scanning across the substrate surface. In some cases, some or all of these captured locations may then be used as overlay alignment references for the following processes (e.g., exposure). If and when a substrate is unloaded and loaded to a new location, these reference locations may be re-captured and analyzed to minimize overlay error. This process, and versions of it, may be utilized at operations 5.1A and 5.1B.

After loading and alignment, the system may perform metrology processing 5.2, which may include scanning 5.2A and remediation processing 5.2B.

Scanning 5.2A may be performed by a metrology subsystem 506, and may include scanning a substrate (e.g., substrate 502B) surface profile. In some embodiments, substrate 502B may correspond to substrate 502A after substrate 502A has been loaded and aligned. In some embodiments, the entire surface area of substrate 502B may be scanned before advancing to the next operation.

Operation 5.2A may produce measurements 504A, representative of real positions and/or real offsets of features and components of the substrate's surface profile, as has been previously discussed throughout the present disclosure. Such measurements can be transferred to a computing subsystem (e.g., computing subsystem 508) for remediation processing (operation 5.2B).

Remediation processing may include analyzing the collected measurements 504A and determining remediations (e.g., updates) for an exposure template of the substrate. In embodiments, determining remediations includes determining one or more changes or offsets to apply to a template to be used for performing lithographic exposure of the substrate. The changes or offsets may be determined to address differences between planned positions of contact points to be made electrical connection endpoints and actual locations of the contact points. Remediation processing may then produce an updated template 504B for the substrate to be exposed.

In some embodiments, after scanning 5.2A in the scanning portion of the stage, the substrate (e.g., substrate 502C) may be collected and transferred to the exposure portion of the stage via the system 504. In some embodiments, substrate 502C may be substrate 502B, after scanning has been completed. In some embodiments, loading and aligning to may be repeated (seen at operation 5.1B) in a similar manner to the function of operation 5.1A.

In some embodiments, the scanning portion and exposure portion may correspond to a single stage, in other embodiments, such portions may reside on different stages. In some embodiments, substrate 502D may be substrate 502C after it has been loaded and aligned to within the exposure portion of the stage and system.

In some embodiments, exposure processing 5.3 may then expose (seen at operation 5.3 and operation 5.3A) a loaded and aligned substrate (e.g. substrate 502D) through an exposure subsystem 510 according to an updated template (e.g., updated template 504B) including remediation updates. In such a way, a final substrate 502E can be produced that includes accurate and robust connection paths and points based on the real data that has been captured from the metrology subsystem, and remediation updates to the exposure template.

In some embodiments, the above process can be performed with multiple substrates such that while a substrate is being metrologically scanned, a previously scanned substrate is being lithographically exposed. The substrates can then be removed, with the scanned substrate being moved to the portion of the stage for lithographic exposure, and the exposed substrate transferred to further manufacturing processes (out of the scope of this disclosure). In some embodiments, a new, unprocessed substrate can then be placed on the portion of the stage for metrological scanning. In such a way, processing may be done in parallel, and throughput can be increased.

Turning now to FIG. 6, as was discussed above, in some embodiments of a lithographic system, the scanning portions and exposure portions and systems may not be combined, and may have varying axes or be different units. In an illustration of one such embodiment, FIG. 6 illustrates a top-down view of a lithographic processing system 600, in accordance with some embodiments of the present disclosure.

In some embodiments, the lithographic processing system 600 may have lithographic exposure units 620A-N and metrological scanning units 610A-N that are separate. In some embodiments, metrological scanning units 610A-N can be separate from exposure units 620A-N by being attached to different bridges. For example, scanning units 610A-N can be attached to bridge 606A, while exposure units 620A-N may be attached to bridge 606B (in some cases this may be reversed). In some embodiments, exposure units 620A-N and scanning units 610A-N may be attached to a single bridge, but still maintain a spacing (e.g., D2) between the types of units.

Although system 600 incorporates distinctions from system 200 and/or 400 (as described in FIGS. 2 and/or 4), many similarities may exist between the systems. For example, such systems may incorporate similar styles or embodiments of projected areas, one or more similar substrates, processing areas, bridges, stages, etc. Furthermore, such a system may translate the stage, perform metrological scanning, perform template remediation, perform lithographic exposure, and generally perform these and other functions, or combinations of such functions, in a similar manner as was described with respect to FIGS. 2 and/or 4. Accordingly, components and functions of system 400 that include similarities to components and functions of system 200 and/or 400 (as were discussed with respect to FIGS. 2 and/or 4), may be interpreted as similar, or analogous, and incorporate and augment at least the embodiment discussed therein, mutatis mutandis.

As discussed above, scanning units 610A-N can be attached to bridge 606A, while exposure units 620A-N may be attached to bridge 606B (in some embodiments this may be vice versa). However, in some embodiments, only a single bridge may be used, and scanning and exposure units can be mounted on either side, or otherwise incorporate a space such as D2 between the two types of units. For example, in a variation of the embodiment seen in FIG. 6, scanning units and exposure units might be attached to the same bridge (e.g., either 606A or 606B), with exposure units in a linear configuration with respect to the y axis (e.g. all exposure units may be attached to the right side of the bridge 606A), while the scanning units may also be in a linear configuration with respect to the Y axis, but may be offset from the exposure units (e.g. all the scanning units may be attached to the left side of the bridge 606A). Such an offset (including embodiments, with one, two, or more bridges) may facilitate processing a single substrate (e.g., substrate 602) on stage 604, by performing scanning and exposure closely in time.

In the embodiment of FIG. 6, system 600 may perform metrological scanning and lithographic exposure in a piecewise manner. To begin, an unprocessed substrate (e.g., substrate 602) may first be placed on stage 604 for processing. The system may translate and scan the surface profile of the substrate through scanning units 610A-N, processing areas 614A-N, and scan paths 612A-N(in some embodiments, in a similar manner as discussed with respect to FIG. 2, and through similar components as described therein). As the stage translates, the distance D2 can serve to give the scanning units time to scan (e.g., by giving them a “head-start”), and giving the computing subsystem time to process remediations and update the exposure template, before the exposure units expose the substrate surface, as translation is occurring. Accordingly, exposure units 620A-N may closely (e.g., by distance D2), follow behind scanning units, and perform exposure according to the updated template. Thus, in some embodiments, the stage may only translate once. The system 600 may capture data from the surface profile of the substrate, determining offsets and variations, update a target template for the surface profile, and expose the substrate surface-all within a single sequence of stage movement. As discussed previously, such a system 600 may translate, scan, remediate, expose, and generally perform functions similarly, or analogous, to system 200 (as were discussed with respect to FIG. 2) and in such cases incorporate at least the embodiment discussed therein, mutatis mutandis.

In some embodiments, the distance D2, and speed of translation is such that there is time interval between the scanning unit, and then the exposure unit, passing over a portion of the surface area. During that time interval, the computing subsystem may analyze the portion that has been scanned, generate remedial updates for that portion of the target exposure template, and transmit the updated template to the exposure unit.

In some embodiments, system 600 may have the advantage of not having to remove or transfer the substrate between scanning and exposure processes, thus limiting the introduction of system variations, offsets, and/or errors.

In some embodiments, after a substrate has been processed, a substrate transfer mechanism, such as a robot, or human operator, etc. can remove substrates from stage 604, and fetch a new, unprocessed substrate for the system to process.

In some embodiments, such a system can be expanded to process more substrates in parallel. For example, in some embodiments, the stage, and the bridge, may be lengthened in the Y direction to accommodate more substrates and/or more lithographic processing units to process additional substrates in parallel. In some embodiments, the stage may be lengthened, and further bridges and lithographic processing units may be added in the X direction. Thus, a variety of configurations, to incorporate more (or less) than two substrates, and process them in parallel, may be applied to the lithographic processing system. One of ordinary skill in the art, having the benefit of this disclosure, will be able to design a lithographic processing system that processes more than two, or any number of substrates, of any dimensions, in parallel according to the above method.

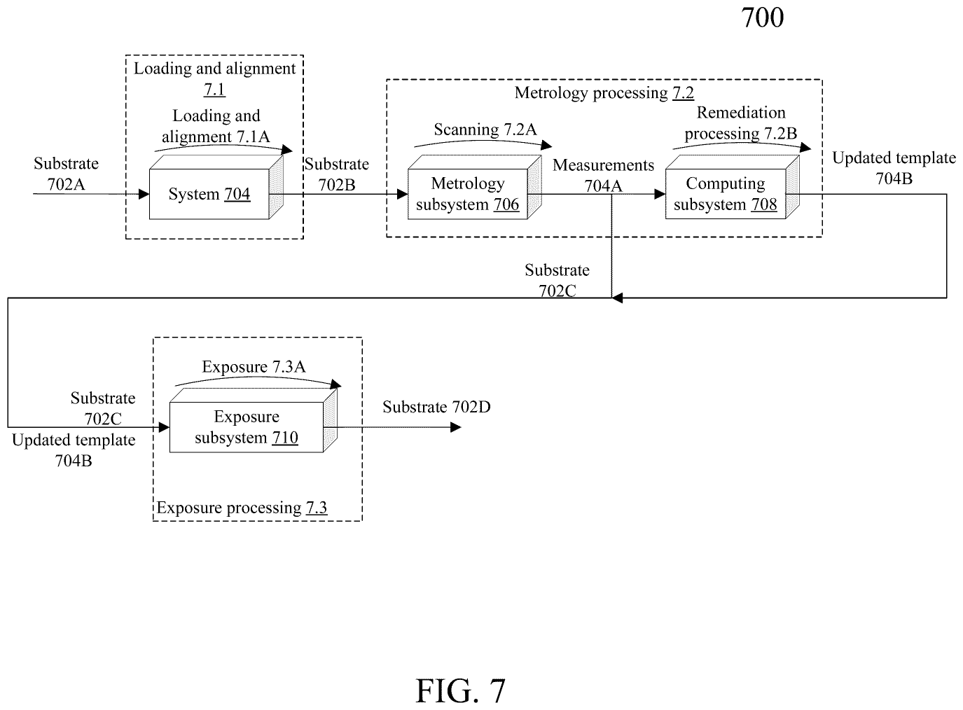

FIG. 7 illustrates an example process flow of a substrate through the system of FIG. 6, in accordance with some embodiments of the present disclosure.

In some embodiments, process 700 of FIG. 7, may use the system 600 of FIG. 6. Accordingly, in some embodiments, process 700 may include methods and components similar to, or analogous to, processes and components of FIG. 6, and include at least the embodiments discussed therein with respect to the components of FIG. 6. Such similar methods and components may include the system 704 (similar or analogous to system 400), metrology subsystem 706 (similar, analogous to, or incorporating scanning units 410A-N), remediation processing 7.2B (not labeled, but described, in FIG. 6), and/or exposure subsystem 710 (similar, analogous to, or incorporating exposure units 620A-N).

Process 700 may begin with loading and alignment (operation 7.1). In such an operation, a system 704 may load and align to a substrate 702A onto a stage for processing (e.g., scanning and exposure). This operation may involve similar methods and strategies as operation 5.1 (“load and alignment”), as described with respect to FIG. 5, and incorporate and augment at least the embodiments described therein, mutatis mutandis.

After loading and alignment, the system may perform metrology processing 7.2, which may include scanning 7.2A and remediation processing 7.2B

Scanning 7.2A may be performed by a metrology subsystem 706, and may scan a substrate (e.g., substrate 702B) surface profile. In some embodiments, substrate 702B may be substrate 702A, after substrate 702A has been loaded and aligned to.

Operation 7.2A may produce measurements 704A, representative of real positions and/or real offsets of features and components of the substrate's surface profile, as has been previously discussed throughout the present disclosure. Such measurements can be transferred to a computing subsystem (e.g., computing subsystem 708) for remediation processing (operation 7.2B).

Remediation processing may analyze the collected measurements 704A and determine necessary remediations (e.g., updates) for an exposure template of the substrate. In embodiments, determining remediations includes determining one or more changes or offsets to apply to a template to be used for performing lithographic exposure of the substrate. The changes or offsets may be determined to address differences between planned positions of contact points to be made electrical connection endpoints and actual locations of the contact points. Remediation processing may then produce an updated template 704B for the substrate to be exposed.

As was discussed with respect to FIG. 6, such scanning, and remediation processing can occur concurrently with exposure, as the scanning subsystem can lead the exposure system by some distance. As such, the scanning portion can scan a portion, or region of the substrate, remediation can update the template for that portion or region of the substrate, and exposure can relatively quickly expose the portion. In such a lagging method, the exposure unit can “trail” the scanning units. Thus, in such an embodiment, the remediation processing may only be for portions, or regions, of the scanned surface (e.g., the portion of the substrate that the metrology subsystem has scanned in between the metrology units and the exposure units).

In some embodiments, exposure processing 7.3 may then expose (seen at operations 7.3 and operation 7.3A) the substrate (e.g. substrate 702C) through an exposure subsystem 710 according to an updated template (e.g., updated template 704B) including remediation updates. In some embodiments, substrate 702C may be substrate 702B (scanning and processing may be done concurrently). In such a way, a final substrate 702D can be produced that includes accurate and robust connection paths and points based on the real data that has been captured from the metrology subsystem, and remediation updates to the exposure template.

In some embodiments, the above process can be performed with multiple substrates via an expanded stage. Thus, any one of the above-described processes can apply to one or more substrates. After a substrate has been fully processed, the substrate can be removed, and transferred to further manufacturing processes (out of the scope of this disclosure). In some embodiments, a new, unprocessed substrate can then be placed onto the stage. In such a way, processing may be done in parallel, and throughput can be increased.

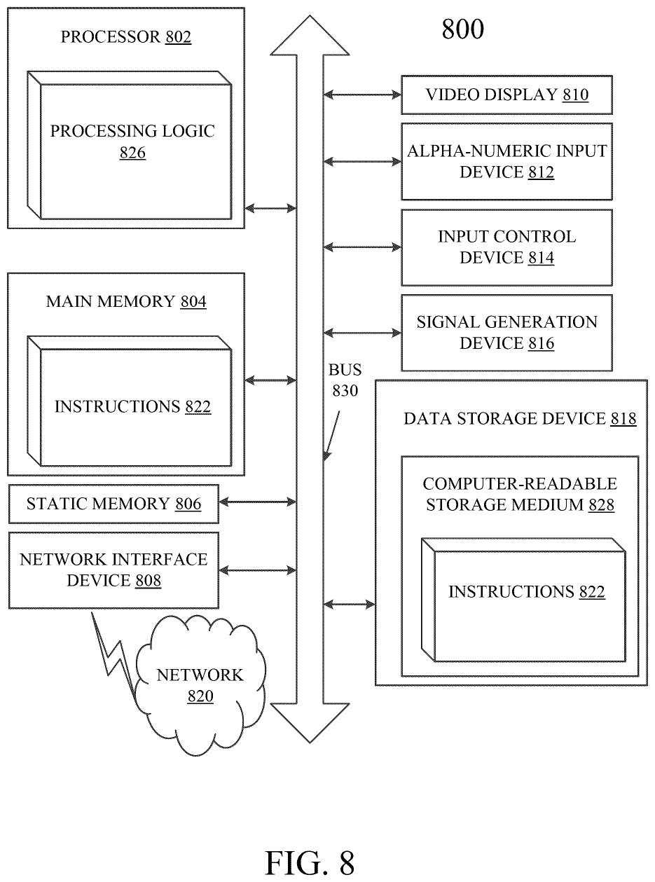

FIG. 8 illustrates an embodiment of a diagrammatic representation of a computing device associated with a substrate manufacturing system. In one implementation, the processing device 800 may be a part of any computing device associated with any of the above described figures, or any combination thereof. Example processing device 800 may be connected to other processing devices in a LAN, an intranet, an extranet, and/or the Internet. The processing device 800 may be a personal computer (PC), a set-top box (STB), a server, a network router, switch or bridge, or any device capable of executing a set of instructions (sequential or otherwise) that specify actions to be taken by that device. Further, while only a single example processing device is illustrated, the term “processing device” shall also be taken to include any collection of processing devices (e.g., computers) that individually or jointly execute a set (or multiple sets) of instructions to perform any one or more of the methods discussed herein.

Example processing device 800 may include a processor 802 (e.g., a CPU), a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 818), which may communicate with each other via a bus 830.

Processor 802 represents one or more general-purpose processing devices such as a microprocessor, central processing unit, or the like. More particularly, processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. In accordance with one or more aspects of the present disclosure, processor 802 may be configured to execute instructions (e.g. instructions 822 may include a computing subsystem as seen at least in FIGS. 5 and 7.).

Example processing device 800 may further comprise a network interface device 808, which may be communicatively coupled to a network 820. Example processing device 800 may further comprise a video display 810 (e.g., a liquid crystal display (LCD), a touch screen, or a cathode ray tube (CRT)), an alphanumeric input device 812 (e.g., a keyboard), an input control device 814 (e.g., a cursor control device, a touch-screen control device, a mouse), and a signal generation device 816 (e.g., an acoustic speaker).

Data storage device 818 may include a computer-readable storage medium (or, more specifically, a non-transitory computer-readable storage medium) 828 on which is stored one or more sets of executable instructions 822. In accordance with one or more aspects of the present disclosure, executable instructions 822 may comprise executable instructions.

Executable instructions 822 may also reside, completely or at least partially, within main memory 804 and/or within processor 802 during execution thereof by example processing device 800, main memory 804 and processor 802 also constituting computer-readable storage media. Executable instructions 822 may further be transmitted or received over a network via network interface device 808.

While the computer-readable storage medium 828 is shown in FIG. 8 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplarily language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

A digital computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a digital computing environment. The essential elements of a digital computer a central processing unit for performing or executing instructions and one or more memory devices for storing instructions and digital data. The central processing unit and the memory can be supplemented by, or incorporated in, special purpose logic circuitry or quantum simulators. Generally, a digital computer will also include, or be operatively coupled to receive digital data from or transfer digital data to, or both, one or more mass storage devices for storing digital data, e.g., magnetic, magneto-optical disks, optical disks, or systems suitable for storing information. However, a digital computer need not have such devices.

Digital computer-readable media suitable for storing digital computer program instructions and digital data include all forms of non-volatile digital memory, media and memory devices, including by way of example semiconductor memory devices, e.g., EPROM, EEPROM, and flash memory devices; magnetic disks, e.g., internal hard disks or removable disks; magneto-optical disks; CD-ROM and DVD-ROM disks.

Control of the various systems described in this specification, or portions of them, can be implemented in a digital computer program product that includes instructions that are stored on one or more non-transitory machine-readable storage media, and that are executable on one or more digital processing devices. The systems described in this specification, or portions of them, can each be implemented as an apparatus, method, or system that may include one or more digital processing devices and memory to store executable instructions to perform the operations described in this specification.

While this specification contains many specific embodiment details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A digital lithography system comprising:
a stage configured to support a substrate;
a bridge disposed above the stage; and
a first lithographic processing unit coupled to the bridge, comprising:
an optical system configured to transmit optical signals both to and from the substrate and the first lithographic processing unit;
a scanning unit configured to capture measurements associated with the substrate via the optical system; and
a lithographic exposure unit configured to perform digital lithographic exposure of the substrate via the optical system.

2. The digital lithography system of claim 1, further comprising:
a controller configured to:
cause the first lithographic processing unit to capture the measurements of the substrate at a first time during a measurement operation;
determine remedial updates for a lithographic exposure pattern based on the measurements; and
cause the first lithographic processing unit to perform the digital lithographic exposure of the substrate according to the lithographic exposure pattern as adjusted by the remedial updates at a second time during an exposure operation.

3. The digital lithography system of claim 1, further comprising:
a plurality of adjacent processing regions spanning a surface profile of the substrate, wherein the first lithographic processing unit is positioned to operate on a first processing region of the plurality of adjacent processing regions; and
one or more additional lithographic processing units, each of the one or more additional lithographic processing units is positioned to operate on an additional processing region of the plurality of adjacent processing regions at a same time that the first lithographic processing unit is to operate on the first processing region.

4. The digital lithography system of claim 1, wherein the lithographic exposure unit comprises an actinic light source and a spatial light modulator, and scanning unit comprises an image sensor.

5. The digital lithography system of claim 1, wherein the first lithographic processing unit further comprises a first brightfield light source.

6. The digital lithography system of claim 5, wherein the scanning unit further comprises a second brightfield light source or a darkfield light source.

7. The digital lithography system of claim 5, wherein the scanning unit further comprises a second brightfield light source and a darkfield light source.

8. The digital lithography system of claim 1, wherein the optical system, the scanning unit, and the lithographic exposure unit transmit and receive optical signals along a common longitudinal axis of the first lithographic processing unit.

9. The digital lithography system of claim 1, wherein the optical system comprises reduction optics configured to reduce an image of a lithographic mask pattern onto a surface of the substrate.

10. The digital lithography system of claim 1, wherein the stage is configured to support the substrate at a first region and is further configured to support a second substrate at a second region, the digital lithography system further comprising:
a second lithographic processing unit coupled to the bridge, comprising:
a second scanning unit;
a second lithographic exposure unit; and
a second optical system shared by the second scanning unit and the second lithographic exposure unit;
wherein the second scanning unit is to use the second optical system to generate measurements of the second substrate during a measurement operation, and wherein the second lithographic exposure unit is to use the second optical system to perform digital lithographic exposure of the second substrate using the second optical system during an exposure operation.

11. The digital lithography system of claim 2, further comprising:
a chuck to clamp the substrate to the stage prior to the measurement operation or the exposure operation, wherein the clamp of the substrate to the stage is not released until after the exposure operation.

12. The digital lithography system of claim 11, wherein the chuck comprises an electrostatic chuck.

13. A digital lithography system comprising:
a stage configured to support a first substrate at a first region and a second substrate at a second region;
a bridge disposed above the stage;
a first scanning unit coupled to the stage and disposed above the stage at the first region; and
a first lithographic exposure unit coupled to the stage and disposed above the stage at the second region;
wherein the first lithographic exposure unit is to perform digital lithographic exposure of a first substrate disposed at the second region at a same time that the first scanning unit is to generate measurements of a second substrate disposed at the first region.

14. The digital lithography system of claim 13, further comprising:
a controller to:
cause the first scanning unit to generate the measurements of the second substrate at a first time; and
cause the first lithographic exposure unit to perform the digital lithographic exposure of the first substrate at the first time.

15. The digital lithography system of claim 14, further comprising:
a robotic system to move the first substrate off of the second region of the stage, to move the second substrate from the first region of the stage to the second region of the stage, and to move a third substrate to the first region of the stage;
wherein the controller is further to:
determine remedial updates for a lithographic exposure pattern for the second substrate based on the measurements;
cause the first scanning unit to generate measurements of the third substrate at a second time; and
cause the first lithographic exposure unit to perform digital lithographic exposure of the second substrate according to the lithographic exposure pattern as adjusted by the remedial updates at the second time.

16. The digital lithography system of claim 13, further comprising:
a first plurality of adjacent sub-regions spanning a surface profile of the first region, wherein the first scanning unit is positioned to operate on a first sub-region of the first plurality of adjacent sub-regions;
one or more additional scanning units, wherein each of the one or more additional scanning units is positioned to operate on an additional sub-region of the first plurality of adjacent sub-regions at a same time that the first scanning unit is to operate on the first sub-region;
a second plurality of adjacent sub-regions spanning a surface profile of the second region, wherein the first lithographic exposure unit is positioned to operate on a first sub-region of the second plurality of adjacent sub-regions; and
one or more additional lithographic exposure units, wherein each of the one or more additional lithographic exposure units is positioned to operate on an additional sub-region of the second plurality of adjacent sub-regions at a same time that the first lithographic exposure unit is to operate on the first sub-region of the second plurality of adjacent sub-regions.

17. A digital lithography system comprising:
a stage configured to support a substrate;
a bridge disposed above the stage;
a first scanning unit coupled to the bridge and disposed above the stage at a first region; and
a first lithographic exposure unit coupled to the bridge and disposed above the stage at a second region;
wherein the first scanning unit is to perform scanning of a first portion of the substrate while the first portion of the substrate is positioned in the first region at a first time, and to perform scanning of a second portion of the substrate while the second portion of the substrate is positioned in the first region at a second time; and
wherein the first lithographic exposure unit is to perform digital lithographic exposure of the first portion of the substrate while the first portion of the substrate is positioned in the second region at the second time based at least in part on the scanning performed of the first portion of the substrate at the first time.

18. The digital lithography system of claim 17, further comprising:
a controller to cause the stage to move such that the first portion of the substrate is moved from the first region to the second region, wherein the first lithographic exposure unit is offset from the first scanning unit.

19. The digital lithography system of claim 17, further comprising:
a controller to:
cause the first scanning unit to generate measurements of the first portion of the substrate at a first time;
determine remedial updates for a lithographic exposure pattern for the first portion of the substrate based on the measurements; and
cause the first lithographic exposure unit to perform the digital lithographic exposure of the first portion of the substrate according to the lithographic exposure pattern as adjusted by the remedial updates at the second time.

20. The digital lithography system of claim 17, further comprising:
a first plurality of regions spanning a surface profile of the substrate, wherein the first region is one of the first plurality of regions;
one or more additional scanning units, wherein each of the one or more additional scanning units is positioned to operate on an additional region of the first plurality of regions at a same time that the first scanning unit is to operate on the first region;
a second plurality of regions spanning the surface profile of the substrate, wherein the second region is one of the second plurality of regions; and
one or more additional lithographic exposure units, wherein each of the one or more additional lithographic exposure units is positioned to operate on an additional region of the second plurality of regions at a same time that the first lithographic exposure unit is to operate on the second region.
